(19) United States
(12) Patent Application Publication
(10) Pub. No.: US 2025/0087472 A1
(43) Pub. Date: Mar. 13, 2025

(54) SIMULTANEOUS ETCHING OF MULTI-FACETED SUBSTRATES

(71) Applicant: INTEVAC, INC., Santa Clara, CA (US)

(72) Inventors: Samuel D. Harkness, IV, El Cerrito, CA (US); James Sullivan, Santa Clara, CA (US); Eric C. Lawson, Sunnyvale, CA (US)

(21) Appl. No.: 18/367,759

(22) Filed: Sep. 13, 2023

(51) Int. Cl. H01J 37/32; H01J 37/34

(52) U.S. Cl. CPC H01J 37/32899; H01J 37/3211; H01J 37/32467; H01J 37/32669; H01J 37/32715; H01J 37/32743; H01J 37/3461; H01J 2237/334

(57) ABSTRACT

In an apparatus and related method, a substrate that has multiple facets is held in a chamber of a plasma reactor that has multiple plasma cavities. The substrate is positioned by a transport arrangement with each plasma cavity of the plasma reactor aligned to a facet of the substrate. A plasma is generated in each plasma cavity, to apply simultaneous plasma processing to multiple facets of the substrate.

### FIELD OF THE DISCLOSURE

The field of the present disclosure relates generally to substrate processing and more specifically to plasma processing of substrates, inductively coupled plasma (ICP) and/or plasma processing of substrates for hard disk drives (HDD).

### BACKGROUND

Substrate processing using various techniques and processing equipment for deposition or etching is a vital part of semiconductor processing and hard disk processing. Various chemical species of plasma, and various techniques and related apparatuses for generating, maintaining and applying plasmas, and for etching and deposition are in widespread use in various industries. Examples include impact spatter etching, plasmas formed through radiofrequency (RF) excitement, plasmas formed using remote radiofrequency coupling such as inductively coupled plasma (ICP), and plasmas with ion acceleration. Various transport arrangements position substrates to be processed within a chamber and hold the substrate during processing, such as described in U.S. Pat. No. 9,914,994 titled SYSTEM ARCHITECTURE FOR COMBINED STATIC AND PASS-BY PROCESSING, and U.S. Pat. No. 6,919,001 titled DISK COATING SYSTEM, both of which are assigned to Intevac, Inc. (the assignee of the present disclosure) and are herein incorporated by reference in their entirety into the present specification. Yet, there are problems with known equipment and techniques, and an ongoing need for improvements leading to higher processing throughput and/or higher quality end product. It is in this environment that present embodiments arise.

### SUMMARY

The following summary of the invention is included in order to provide a basic understanding of some aspects and features of the invention. This summary is not an extensive overview of the invention, and as such it is not intended to particularly identify key or critical elements of the invention, or to delineate the scope of the invention. Its sole purpose is to present some concepts of the invention in a simplified form as a prelude to the more detailed description that is presented below.

Embodiments and aspects of an inductively coupled plasma (ICP) station, and related method, are described.

In an embodiment, an ICP station includes a plasma reactor that has a vacuum chamber. The vacuum chamber has a first plasma cavity supporting a first plasma and a second plasma cavity supporting a second plasma. A transport arrangement transports and positions a substrate to be processed within the chamber, with the first plasma cavity aligned to a first axis that is normal to a first facet of the substrate and the second plasma cavity aligned to a second axis that is normal to a second facet of the substrate. Simultaneous processing is applied to the first facet and the second facet of the substrate using the first plasma and the second plasma. In one embodiment, a magnetic field generator is positioned around the chamber to generate magnetic flux in an annular region of the chamber, for each plasma cavity. The magnetic flux acts as bucking magnetic fields that inhibit electron travel to grounded surface(s) of the processing chamber.

In an embodiment, a substrate is held in a chamber of a plasma reactor, using a transport arrangement to position the substrate. In an embodiment the transport arrangement includes carriers that transport the substrates into the chamber, support the substrates within the chamber during processing, and then transport the substrates out of the chamber, serially one after another. A first plasma cavity of the plasma reactor is aligned to a first axis that is normal to a first facet of the substrate. A second plasma cavity of the plasma reactor is aligned to a second axis that is normal to a second facet of the substrate. The substrate is biased. Plasma is generated in each plasma cavity, to apply simultaneous plasma processing to first and second facets of the substrate. In one embodiment, a magnetic field generator is used to provide magnetic flux in an annular region of the chamber. The magnetic flux acts as bucking magnetic fields that inhibit electron travel to a grounded surface of the chamber, for each plasma cavity.

Other aspects and advantages of the embodiments will become apparent from the following detailed description taken in conjunction with the accompanying drawings which illustrate, by way of example, the principles of the described embodiments.

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by one skilled in the art without departing from the spirit and scope of the described embodiments.

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements and are not drawn to scale.

FIG. 1A depicts an embodiment of an inductively coupled plasma (ICP) station for static concentric etch, showing an exterior of an apparatus.

FIG. 1B depicts an embodiment of an inductively coupled plasma (ICP) station for static concentric etch, showing an interior of an apparatus.

FIG. 2 depicts a cross section of the ICP station of FIG. 1A.

FIG. 3 depicts a cross section of a variation of the ICP station of FIG. 1A, with spacers.

FIG. 4 depicts a cross-section of a confinement cylinder, showing an arrangement of magnets as suitable for an embodiment of an ICP station.

FIG. 5 depicts a halo assembly with substrate holder as suitable for an embodiment of an ICP station.

FIG. 6 depicts a method of operation of an ICP station as suitable for practice using embodiments described herein.

FIG. 7A depicts an embodiment of a coil as suitable for an embodiment of an ICP station.

FIG. 7B depicts another embodiment of a coil as suitable for an embodiment of an ICP station.

### DETAILED DESCRIPTION

Embodiments of the inventive etch system will now be described with reference to the drawings. Different embodiments may be used for processing different substrates or to achieve different benefits, such as throughput, etch uniformity, RF power utilization, etc. Depending on the outcome sought to be achieved, different features disclosed herein may be utilized partially or to their fullest, alone or in combination with other features, balancing advantages with requirements and constraints. Therefore, certain features and benefits will be highlighted with reference to different embodiments, but are not limited to the disclosed embodiments, and the features may be incorporated in other embodiments or with other combinations.

A system and related method for simultaneous etching of multi-faceted substrates is described herein, in various embodiments and in various aspects that can be combined in various embodiments applicable to substrate processing. An inductively coupled plasma (ICP) station and a method of operation of an ICP station are described as examples with variations. These present technological solution(s) to the following technological problem.

In the course of simultaneously processing multiple facets of substrates (e.g., front and back sides or opposite faces of a substrate), etch removal rates with known equipment and techniques are found too low to facilitate economic considerations. This is especially problematic when the best method of removal is impact sputter etching as is generally the case for metal surfaces. Moreover, as the removal rate scales with the density of capable species, plasmas formed at pressures greater than are sustainable for gridded sources are required. Such plasmas are typically formed using remote radio frequency (RF) coupling, such as inductively coupled plasma (ICP). While this technique is utile to generate the desired plasma density, the species (ions and radicals) form essentially adiabatically. Therefore, a cathode potential is required to generate the requisite acceleration of ion species to facilitate energetic etching. One method, e.g., an alternative to or augmentation of ICP, uses capacitive coupling of the plasma to enable a biasing function. However, this technique is not straightforward in application when attempting simultaneous etching of both sides or faces of a flat substrate because it requires an insulating housing to surround the area to be etched. This is particularly intractable for such applications wherein the substrate is an annular surface (e.g., a recording disc, or a hard disk for hard disk drives).

Technological solutions disclosed herein to the above problem(s) make use of multiple plasma cavities, each aligned to a specific facet (e.g., face, side or surface) of a substrate. For example, in a plasma reactor that has a processing chamber for processing a substrate, one plasma cavity is aligned to one face of a substrate and another plasma cavity is aligned to another face of the substrate. This enables simultaneous processing of multiple facets of the substrate, for example both faces of a wafer or hard disk. Further embodiments with other numbers of plasma cavity for processing substrates that have other numbers of facets to be processed are readily developed in keeping with the teachings herein. Some embodiments further solve technological problems by providing magnetic flux in the processing chamber to act as bucking magnetic fields that inhibit electron travel to a grounded surface of the processing chamber. Operating conditions and principles for specific examples are described below, followed by description of aspects of embodiments with reference to drawings.

A plasma reactor for round substrates has a cylindrical cavity, as a processing chamber, that is evacuated to a vacuum condition, e.g., below 1 millitorr, with a sample substrate situated in the middle of the cylindrical cavity and oriented to face opposed ends of the cylindrical cavity. Each end of the cylindrical cavity or processing chamber forms a plasma cavity oriented to one face of the sample substrate. Gas desired for etch processing is re-introduced into the cavity at pressures between 0.5 and 30 mTorr, following the evacuation. Typical gases include Ar, Kr, Xe and others for energetic etching, and O2, H2, HN2, SF6 and others for reactive processing.

Plasma forms by applying an RF power to a coil situated as shown in the drawings at high frequencies (e.g., 13.6 MHz) ex-situ to a dielectric quartz window at the back of the cylinder structure, for each plasma cavity, e.g., two coils for two plasma cavities for processing a two-sided or double-faced substrate. The inductive coupling and plasma excitation creates a high fraction of ionized species. Self-extinction issues at the reactor walls are limited by the imposition of designed bucking magnetic fields to inhibit electron travel to the grounded surface, e.g., interior wall(s) in the plasma cavities or processing chamber.

In this way, plasma ion species saturate the cavity region area are then used to facilitate uniform erosion of the sample substrate opposite the back chamber wall/window for plasma etching, or uniform deposition to the sample substrate for plasma deposition, i.e., as processing dependent. The ions are extracted from the dense plasma region by the attractive electrostatic forces provided by the bias charged substrate. This is accomplished favorably by removing the high plasma density region from direct contact with the sample holder to not create conductive shorts to ground. For example, suitable design dimensions for the plasma cavities and the processing chamber overall should be employed and/or dimensions of the processing chamber and spacing of substrate to end-walls of the plasma cavities can be adjusted through the use of spacers in some embodiments. Various embodiments allow the simultaneous processing of multiple facets (e.g., the front and back side of a disk, disc, planar annulus, wafer or other substrate). Each facet or side has a unique relationship with a plasma source (e.g., RF generator) and corresponding plasma cavity (as described). The etch rate is then governed by application of a DC-bias to the substrate holder.

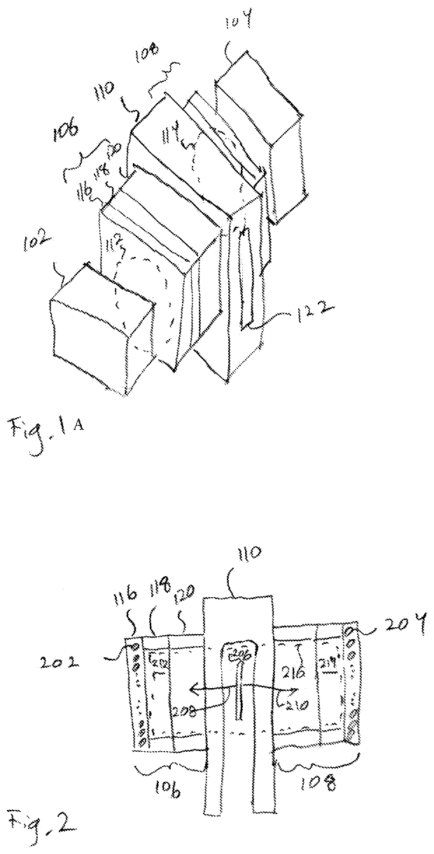

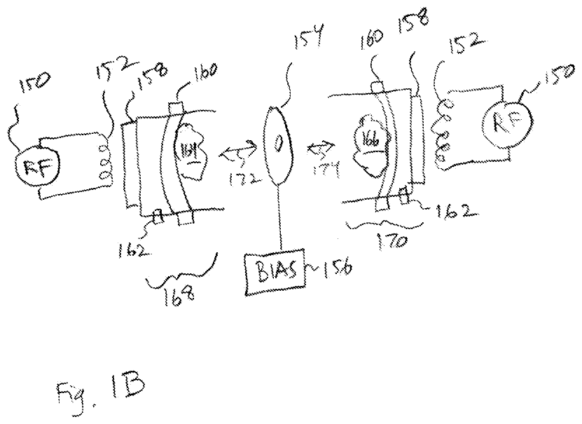

FIG. 1A depicts an embodiment of an inductively coupled plasma (ICP) station for static concentric etch, showing an exterior of an apparatus. By static concentric etch, it is meant that the substrate does not move during etching, and uniform etch in the direction of the axis, i.e., rotational uniformity and depth uniformity, is achieved. Plasma generated by the apparatus, e.g., a plasma reactor, is applied to process a substrate held in a processing chamber (not shown in FIG. 1A, but see FIGS. 1B and 2). To generate the plasma, RF power is applied from a power supply 102, 104 to coils 112, 114 (indicated by dashed lines) each positioned at a closed end of a plasma cavity (see FIG. 2). In one embodiment, each power supply 102, 104 is an RF power source, tunable for resonance when energizing the coil to generate the plasma. Physical and electrical connections from power supply 102, 104 to coils 112, 114 is not shown in FIG. 1A, but is readily devised for this and further embodiments with various locations and types of power supplies as suitable for driving plasma excitement coils.

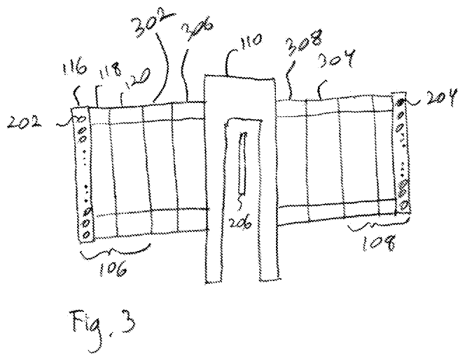

One plasma cavity assembly 106, including a coil 112 in an end cap 116, an adaption cylinder plate 118 and a chamber cylinder section 120, is located to one side of a plasma chamber midsection 110, another plasma cavity assembly 108 (with similar design and parts) is located to another side, in this example the opposed side, of the plasma chamber midsection 110. For operation in a linear system, where substrate carriers traverse multiple chambers in a linear travel fashion, an aperture 122 in the plasma chamber midsection 110 provides access to the plasma chamber for a substrate holder entering the chamber, and a complementary aperture is provided on the opposite wall for the substrate carrier to exit the chamber. The apertures can be sealed with gate valves, not shown in FIG. 1. In various embodiments as further described below, magnets located in the chamber cylinder section 120, for example embedded in the wall(s), are a magnetic field generator positioned around the chamber to generate magnetic flux that acts as bucking magnetic fields, in the processing chamber. Various magnetic field generators, using permanent magnets or electromagnetism are envisioned. Also, some embodiments are adjustable to size the processing chamber and relative location of the substrate, through the use of spacers (see FIG. 3). In one embodiment, a high vacuum pump with a Meisner cold trap is applied to evacuate the processing chamber. In one embodiment, a suitable sequence of operation is to open a gate valve(s) attached to the aperture 122 and the exit aperture, swap the substrate carriers, close the gate valves, fill with gas, activate plasmas and sputter (i.e., sputter processing) for simultaneous processing of all facets of the substrate, pump out, and repeat.

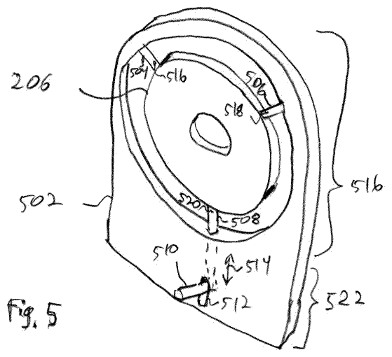

FIG. 1B depicts an embodiment of an inductively coupled plasma (ICP) station for static concentric etch, showing an interior of an apparatus. A substrate 154, in this example a disk for a hard drive, is held by a substrate carrier (see FIG. 5) and is oriented vertically and positioned with each face (or facet) of the substrate facing a respective plasma distribution zone 168, 170. A bias source 156 is electrically connected to the substrate 154 and provides, in this example, a DC bias to the substrate 154. To the left of the substrate 154, one plasma distribution zone 168 has a plasma 164 excited by a coil 152 driven by an RF source 150 that is inductively coupled to the plasma 164 through a dielectric window 158. A magnet arrangement 160 is arranged to provide magnetic confinement of the plasma 164 at a defined spacing 172 to the respective face of the substrate 154. To the right of the substrate 154, another plasma distribution zone 170 has another plasma 166 excited by another coil 152 driven by another RF source 150 that is inductively coupled to the plasma 166 through a dielectric window 158. Another magnet arrangement 160 is arranged to provide magnetic confinement of the plasma 166 at a defined spacing 174 to the respective face of the substrate 154. Gas nozzles 162 introduce gas into each plasma distribution zone 168, 170. The DC bias attracts ions from each plasma 164, 166 for energetic impact to the respective faces (or facets) of the substrate 154, so that simultaneous processing of both (all) facets of the substrate 154 is performed by the apparatus, using plasmas 164, 166 (or, collectively, portions of a plasma) that are in plasma distribution zones 168, 170 oriented to the facets of the substrate 154. In one embodiment, the gas nozzles 162 are positioned to introduce gas behind the magnetic confinement, so that the gas then develops into the plasma in the plasma distribution zone 168, 170, but it is less likely that un-ionized gas strays into the vacuum region between the plasma and the substrate 154 to interfere with ion travel to the substrate 154. Stated another way, the magnetic arrangement is positioned between the substrate and the gas nozzles, thereby confining the plasma to an area between the substrate and the gas injection nozzle. Such positioning of gas nozzles 162 is believed optimal, in comparison with positioning gas nozzles closer to the substrate than the plasma distribution zone, or adjacent to the substrate 154. In various embodiments, the magnet arrangement 160 that provides magnetic confinement of the plasma uses permanent magnets, electromagnets, or both, to produce magnetic flux that acts as bucking fields and keeps the plasma from grounding to chamber walls.

Previous methods and apparatuses have used a gas source, RF coil and plasma for only one sided processing of a substrate. Attempting to insert a two-sided (or multiple faceted) substrate into the middle of a plasma in such apparatuses has disrupted the plasma, preventing plasma processing of the side of the substrate facing away from the RF energized coil. Present embodiments improve upon such previous methods and apparatuses, and present a technological solution to this technological problem, through the use of multiple plasma distribution zones each oriented to a respective facet of a multi-faceted substrate.

FIG. 2 depicts a cutaway cross section view of the ICP station of FIG. 1A. This cross-section is taken vertically, from end to end of the apparatus, longitudinally along the processing chamber 216 (illustrated in dashed lines), showing a substrate 206 with normals 208, 210 to the opposed faces of the substrate illustrated by arrows, where the normals 208, 210 are along the rotational axis of the substrate. The substrate 206 is positioned vertically in the middle of the processing chamber 216, with opposed faces of the substrate 206 each facing a respective end of the apparatus and each face of the substrate aligned with a plasma cavity. Here, one plasma cavity 212 (a portion of the processing chamber 216) is aligned along an axis (e.g., a cylindrical center axis) to one normal 208 corresponding to one face of the substrate 206, and another plasma cavity 214 is aligned along an axis to the opposed normal 210 corresponding to the opposed face of the substrate 206. With such alignment, each plasma cavity 212, 214 is associated to a respective facet of the substrate 206, so that the multiple (e.g., two) plasma cavities 212, 214 participate in simultaneous plasma processing of both (or all) facets of the substrate 206.

Continuing with FIG. 2, at the left end of the drawing, coil windings 202 of the coil 112 (FIG. 1A) are depicted in planar, concentric arrangement in the end cap 116 of the plasma cavity assembly 106. Similarly, coil windings 204 of the coil 114 (FIG. 1A) are in planar, concentric arrangement in the end cap of the opposing plasma cavity assembly 108. In one embodiment, the end cap 116 has the coil windings 202 attached to a window, with clamp(s) fastening the end cap 116 together as an assembly itself, and/or fastening the end cap 116 to other component(s), for example to form plasma cavity assembly 106. The window is made of RF transparent, dielectric material, suitable for inductively coupled plasma, physically separating the coil from the chamber and supporting inductive coupling, for example dielectric quartz or various alumina compounds.

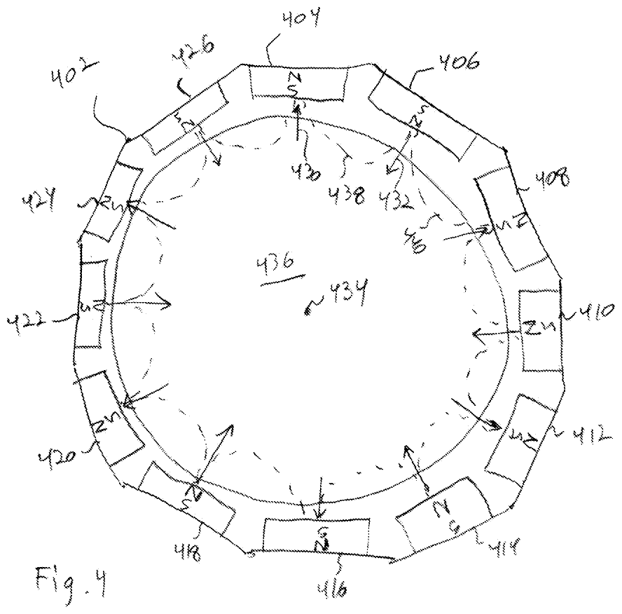

Adaption cylinder plate 118 has cylindrical interior walls, as does chamber cylinder section 120, and these along with end cap 116 form the plasma cavity assembly 106, with plasma cavity assembly 108 being formed similarly as mirrored image. In one embodiment, magnets are arrayed in the chamber cylinder section 120 (see FIG. 4). In various embodiments, similar, identical, or symmetric (e.g., left right mirror image) design and components apply to plasma cavity assembly 108 as plasma cavity assembly 106. The confines (e.g., interior walls) of the two plasma cavity assemblies 106, 108 and the plasma chamber midsection 110 form and define the processing chamber 216, in this embodiment a cylinder (although further shapes are readily developed).

In one embodiment, it has been found that the length of the processing chamber, which is cylindrical in this embodiment, is at least two thirds the diameter of the cylinder, for optimal processing. In one embodiment, it has been found that the length of the cylindrical processing chamber is equal to the diameter of the cylinder, for optimal processing.

FIG. 3 depicts a cutaway cross section view of a variation of the ICP station of FIG. 1A, with spacers 302, 304, 306, 308. The overall length of the processing chamber 216 (see FIG. 2), relative dimensions of length versus width, the relative spacing between the substrate 206 and end cap 116, or relative depth of the plasma cavity 212, 214 can be adjusted for one or both (e.g., all) facets of the substrate or respective plasma cavities, etc., by adding or removing the appropriate spacer(s) 302, 304, 306, 308. Such adjustability may facilitate tuning the apparatus for optimal etching or deposition according to different substrate diameters. Alternatively, the various dimensions could be designed into fewer, more integrated components, and these swapped in or out.

FIG. 4 depicts a cross-section view of a confinement cylinder, showing an arrangement of magnets as a magnetic field generator suitable for an embodiment of an ICP station. In one example, the depicted arrangement of magnets is used as an annular arrangement of magnets, i.e., annular magnet array, in the chamber cylinder section 120 (see FIGS. 2 and 3), in each plasma cavity assembly 106, 108. Example magnetic flux lines 438, 440 are depicted in dashed line. Example magnetization vectors 430, 432 are depicted with arrows. In one embodiment, the magnets are each greater than 5 mm wide, as measured relative to a chord to the annulus. In one embodiment, the magnets are each greater than 20 mm wide.

In one embodiment, polarity from one magnet to its nearest neighbors is opposite, throughout the array. Here, the magnets alternate North, South, North, South, etc., around the annulus, which coincides with the normal to the rotational axis of the substrate (See, FIG. 2). For example, see polarity of one magnet 404, with South pointing towards the center 434 of the annulus, in contrast to polarities of the neighboring magnets 406, 426, each of which has North pointing towards the center 434 of the annulus. This reverse orientation (and corresponding arrangement) applies to each magnet and its nearest neighbor magnets, throughout the array. Variations with other numbers of magnets, electromagnets and orientations are readily devised. It is believed that the alternating orientation of magnets produces fuzzy, broad flux such that there will be deposits at magnet pole center points but deposits are otherwise minimized.

In one embodiment, magnets are polarized through the thickness of the annulus and arranged with alternating or interleaved opposing magnetization vectors around the annulus. For example, magnetization vectors 432 of every other magnet 406, 410, 414, 418, 422, 426 pointing from the magnet towards the center 434 of the annulus are interleaved or alternating with magnetization vectors 430 of every other magnet 404, 408, 412, 416, 420, 424 pointing away from the center of the annulus to the magnet. Variations with other numbers of magnets and orientations are readily devised.

In one embodiment, sidewalls of the plasma reactor are constructed to provide an inner diameter that defines the gas expansion limit, and a slightly larger diameter but concentric wall that creates a pocket for storage of an annular magnetic array, for example as depicted in FIG. 4. In one embodiment, such an outer dimension wall is composed of a material capable of keepering magnetic flux from the magnets so arranged. In this respect, a ‘keeper’ is a piece of iron or steel that is placed between the poles of a permanent magnet to maintain an easy path for the magnet's flux.

FIG. 5 depicts a halo assembly with substrate holder 516 as suitable for an embodiment of an ICP station. The halo assembly, so named because it evokes the appearance of a ring as if a halo for the substrate 206, holds the substrate 206 securely during insertion of the substrate 206 to the processing chamber 216, processing in the processing chamber 216 using plasma applied simultaneously to both sides or all facets of the substrate 206, and removal of the substrate 206 from the processing chamber 216, all of which can be performed mechanically in various embodiments with suitable equipment readily devised. The halo assembly further performs the function of applying electrical bias to the substrate 206 during processing, in some embodiments. The halo assembly may be considered a transport arrangement, or a part of a transport arrangement, in various embodiments. Generally, a transport arrangement positions a substrate to be processed within a chamber. Further examples of transport arrangements, to which the halo assembly and/or various aspects of systems and methods described herein may be applied through modification thereof in various embodiments, are described in U.S. Pat. No. 9,914,994 SYSTEM ARCHITECTURE FOR COMBINED STATIC AND PASS-BY PROCESSING, and U.S. Pat. No. 6,919,001 DISK COATING SYSTEM.

In order to facilitate insertion of the substrate 206 to the holder 516, retention of the substrate 206 by the holder 516, and removal of the substrate 206 from the holder 516, one embodiment of the holder 516 has three prongs 504, 506, 508 that physically contact the substrate 206. One or more of the three prongs 504, 506, 508 also establishes and maintains electrical contact to the substrate 206, for electrical bias of the substrate 206, which is readily achieved with a suitable electrical bias source, connection and control to charge the substrate and sustain current flow. In this embodiment, two of the prongs 504, 506 are fixed in the holder 516, and one prong 508 is movable in a longitudinal direction 514 of the prong 508, i.e., away from and towards the substrate 206. Prong tips 516, 518, 520 could have various features to contact and retain the substrate 206, for example each could have a fork, a cup, a gripper, a channel, texturing, ribs, etc., in various embodiments. In FIG. 5, the movable prong 508 slides back and forth in the halo assembly, for example through a channel or hole in the base 522 of the halo assembly, and has a handle 510 for example formed as a bend in the prong 508 at the end opposite the prong tip 520. The handle 510 could be engaged by a machine. The movable prong 508 could be spring-loaded, or clamped to hold position, and further mechanisms for facilitating insertion, retention and removal are readily devised. Although three prongs 504, 506, 508 are thought sufficient and optimal for retaining the substrate 206 securely and without wobbling due to manufacturing tolerances or wear, embodiments with other numbers, types and arrangements of prongs or other holders are readily devised. Various further shapes and assemblies for the base 522 of the halo assembly, including fasteners, apertures, brackets, etc., are readily devised as appropriate to specific machinery or aesthetics.

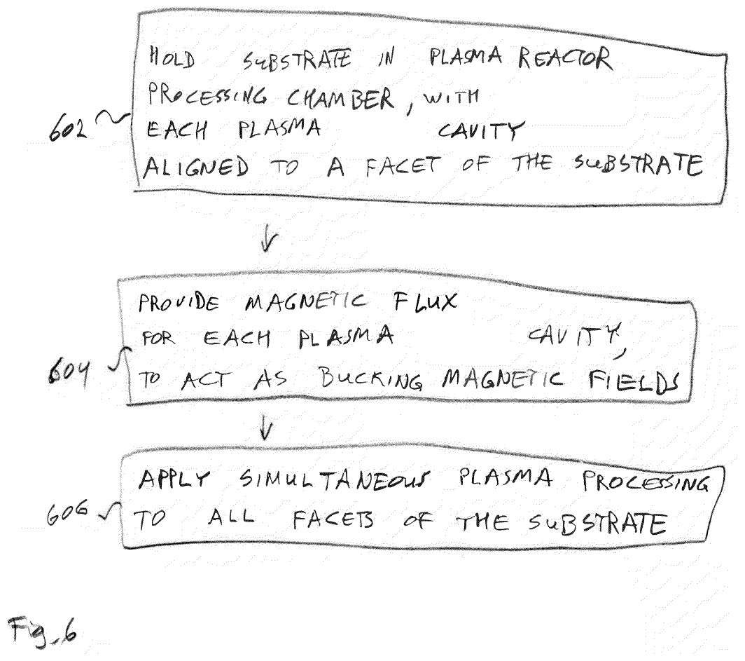

FIG. 6 depicts a method of operation of an ICP station as suitable for practice using embodiments described herein. The method is applicable to various substrates and various numbers of plasma cavities, including two-sided or two-faced substrates processed using two plasma cavities, and substrates with a greater number of facets processed using a corresponding number of plasma cavities, one for each facet. The method can be performed by a plasma reactor that has a plasma reactor processing chamber with multiple plasma cavities.

In an action 602, the apparatus holds a substrate in the plasma reactor processing chamber, with each plasma cavity aligned to a facet of the substrate. For example, a two-sided or two-faced substrate is held with a first plasma cavity aligned to a first side or face of the substrate, and a second plasma cavity aligned to a second side or face of the substrate.

In an action 604, the apparatus provides magnetic flux for each plasma cavity, to act as bucking magnetic fields. The bucking magnetic fields inhibit electron travel to a grounded surface of the processing chamber. For example, annular arrays of magnets, one in each plasma cavity, can provide magnetic flux that so acts.

In an action 606, the apparatus generates a plasma in each plasma cavity, to apply simultaneous processing to all facets of the substrate, for example both sides or faces of a two-sided or two-faced substrate.

In one embodiment, electrical bias is applied to the substrate.

It should be appreciated that, in a variation, it is possible to perform actions 602 and 606 without action 604 and the magnetic flux. This variation may be less optimal, and have less even application of plasma or greater amount of deposits on chamber surfaces, but it is nonetheless possible as an embodiment. Notably, without the application of the magnetic flux electrons from the plasma can travel to the chamber's walls and the plasma would become unstable or it may extinguish.

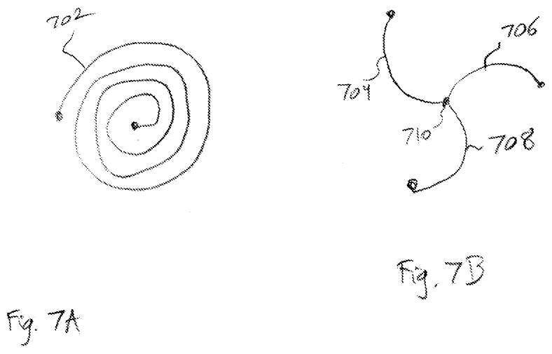

FIG. 7A depicts an embodiment of a coil as suitable for an embodiment of an ICP station. This coil has a single coil filament 702, characterized by the number of planar, concentric windings (in this example, four). Further embodiments, with other numbers of windings, dual or multiple filaments, etc., are possible.

FIG. 7B depicts another embodiment of a coil as suitable for an embodiment of an ICP station. This coil has three coil filaments 704, 706, 708, in planar arrangement joined at the center 710 of the coil and branching in arcuate extension from the center 710. Further embodiments, with other numbers of filaments, other shapes, etc., are possible.

Detailed illustrative embodiments are disclosed herein. However, specific functional details disclosed herein are merely representative for purposes of describing embodiments. Embodiments may, however, be embodied in many alternate forms and should not be construed as limited to only the embodiments set forth herein. It should be appreciated that descriptions of direction and orientation are for convenience of interpretation, and the apparatus is not limited as to orientation with respect to gravity. In other words, the apparatus could be mounted upside down, right side up, diagonally, vertically, horizontally, etc., and the descriptions of direction and orientation are relative to portions of the apparatus itself, and not absolute.

It should be understood that although the terms first, second, etc. may be used herein to describe various steps or calculations, these steps or calculations should not be limited by these terms. These terms are only used to distinguish one step or calculation from another. For example, a first calculation could be termed a second calculation, and, similarly, a second step could be termed a first step, without departing from the scope of this disclosure. As used herein, the term “and/or” and the “/” symbol includes any and all combinations of one or more of the associated listed items.

As used herein, the singular forms “a”, “an” and “the” are intended to include the plural forms as well, unless the context clearly indicates otherwise. It will be further understood that the terms “comprises”, “comprising”, “includes”, and/or “including”, when used herein, specify the presence of stated features, integers, steps, operations, elements, and/or components, but do not preclude the presence or addition of one or more other features, integers, steps, operations, elements, components, and/or groups thereof. Therefore, the terminology used herein is for the purpose of describing particular embodiments only and is not intended to be limiting.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Although the method operations were described in a specific order, it should be understood that other operations may be performed in between described operations, described operations may be adjusted so that they occur at slightly different times or the described operations may be distributed in a system which allows the occurrence of the processing operations at various intervals associated with the processing.

Various units, circuits, or other components may be described or claimed as “configured to”, or “to”, perform a task or tasks. In such contexts, the phrase “configured to” is used to connote structure by indicating that the units/circuits/components include structure (e.g., circuitry or mechanical features) that performs the task or tasks during operation. As such, the unit/circuit/component can be said to be configured to perform the task even when the specified unit/circuit/component is not currently operational (e.g., is not on). The units/circuits/components used with the “configured to” language include hardware—for example, circuits, memory storing program instructions executable to implement the operation, etc. Reciting that a unit/circuit/component is “configured to” perform one or more tasks is expressly intended not to invoke 35 U.S.C. 112, sixth paragraph, for that unit/circuit/component. Additionally, “configured to” can include generic structure (e.g., generic circuitry) that is manipulated by software and/or firmware (e.g., an FPGA or a general-purpose processor executing software) to operate in manner that is capable of performing the task(s) at issue. “Configured to” may also include adapting a manufacturing process (e.g., a semiconductor fabrication facility) to fabricate devices (e.g., integrated circuits or manufactured articles) that are adapted to implement or perform one or more tasks, or designing an article or apparatus to have certain features or capabilities.

The foregoing description, for the purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the embodiments and its practical applications, to thereby enable others skilled in the art to best utilize the embodiments and various modifications as may be suited to the particular use contemplated. Accordingly, the present embodiments are to be considered as illustrative and not restrictive, and the invention is not to be limited to the details given herein, but may be modified within the scope and equivalents of the appended claims.

What is claimed is:

1. An inductively coupled plasma (ICP) station, comprising:
a plasma reactor having a chamber with at least a first plasma cavity with a first plasma distribution zone aligned to a first axis and a second plasma cavity with a second plasma distribution zone aligned to a second axis;
a first plasma source maintaining a first plasma in the first plasma distribution zone of the first plasma cavity; and
a second plasma source maintaining a second plasma in the second plasma distribution zone of the second plasma cavity;
a transport arrangement positioning a substrate to be processed within the chamber with the first axis normal to a first facet of the substrate and the second axis normal to a second facet of the substrate, with simultaneous processing applied to the first facet and the second facet of the substrate using the first plasma and the second plasma.

2. The ICP station of claim 1, further comprising:
a magnetic field generator positioned around the chamber generating magnetic flux in an annular region of the chamber that acts as bucking magnetic fields thereby inhibiting electron travel to a grounded surface of the chamber, for each such plasma cavity.

3. The ICP station of claim 1, wherein
the first and second plasma sources each having a coil couped to an RF source and arranged to inductively couple radio frequencies to gas in the chamber, such that each of the first plasma and the second plasma is an inductively coupled plasma.

4. The ICP station of claim 3, wherein
the coils are formed in concentric, coplanar arrangement to generate electromagnetic field directed into a gas body, for each such plasma cavity.

5. The ICP station of claim 3, further comprising:
the plasma reactor having a back wall comprising dielectric quartz or alumina compound.

6. The ICP station of claim 1, wherein the plasma reactor comprises an annular magnetic array to provide magnetic flux in an annular region of the chamber, for each such plasma cavity.

7. The ICP station of claim 1, wherein a length of the plasma cavity is at least two thirds a diameter of the plasma cavity, for each such plasma cavity.

8. The ICP station of claim 2, wherein a portion of a wall of the chamber comprises material capable of keepering the magnetic flux.

9. The ICP station of claim 1, wherein the plasma reactor comprises a plurality of magnets that are arranged in alternating opposite polarity about an annular array, forming magnetic flux in an annular region of the chamber, for each such plasma cavity.

10. The ICP station of claim 1, wherein the plasma reactor comprises a plurality of magnets arranged in an annulus and having magnetization vectors pointing to a center of the annulus alternating with magnetization vectors pointing from the center of the annulus, for each such plasma cavity.

11. The ICP station of claim 1, wherein the plasma reactor comprises a plurality of magnets each greater than 5 mm wide.

12. The ICP station of claim 1, wherein the plasma reactor comprises a plurality of magnets each greater than 20 mm wide.

13. The ICP station of claim 1, wherein the transport arrangement comprises a substrate holder having electrical bias contact to the substrate, arranged to charge the substrate and sustain current flow.

14. A method of operation of an inductively coupled plasma (ICP) station, comprising:
holding a substrate in a chamber of a plasma reactor, using a transport arrangement to position the substrate with a first plasma cavity and first plasma distribution zone of the plasma reactor aligned to a first axis that is normal to a first facet of the substrate, and with a second plasma cavity and second plasma distribution zone of the plasma reactor aligned to a second axis that is normal to a second facet of the substrate;
biasing the substrate; and
generating a plasma in each such plasma cavity, to apply simultaneous plasma processing to the first and second facets of the substrate.

15. The method of claim 14, further comprising:
using a magnetic field generator to provide magnetic flux in an annular region of the chamber to act as bucking magnetic fields that inhibit electron travel to a grounded surface of the chamber, for each such plasma cavity.

16. The method of claim 12, wherein:
the generating the plasma uses inductive coupling of radio frequencies to gas in the chamber, so that the plasma in each such plasma cavity is an inductively coupled plasma.

17. The method of claim 12, wherein:
the generating the plasma uses coils in concentric, coplanar arrangement in each such plasma cavity, to generate electromagnetic field directed into a gas body.

18. The method of claim 12, wherein:
the providing the magnetic flux comprises arranging an annular magnetic array in each such plasma cavity.

19. The method of claim 12, wherein:
the using the magnetic field generator to provide the magnetic flux comprises using an array of magnets within the plasma reactor and keepering the magnetic flux by having a portion of a wall of the chamber comprising material capable of the keepering the magnetic flux.

20. The method of claim 12, wherein:
the using the magnetic field generator to provide the magnetic flux comprises arranging a plurality of magnets in alternating opposite polarity about an annular array, to provide the magnetic flux in the annular region of the chamber, for each such plasma cavity.

21. The method of claim 12, wherein:
the using the magnetic field generator to provide the magnetic flux comprises the plasma reactor having a plurality of magnets arranged in an annulus and having magnetization vectors pointing to a center of the annulus alternating with magnetization vectors pointing from the center of the annulus, for each such plasma cavity.

22. The method of claim 12, wherein:
the using the magnetic field generator to provide the magnetic flux comprises providing the plasma reactor with a plurality of magnets each greater than 5 mm wide.

23. The method of claim 12, further comprising:
charging the substrate and sustaining current flow through the transport arrangement comprising a substrate holder that provides electrical bias contact to the substrate.
